(19) United States
(12) Patent Application Publication
(10) Pub. No.: US 2026/0338839 A1
(43) Pub. Date: Oct. 29, 2026

(54) VOLTAGE CHANGE DETECTION CIRCUIT

(71) Applicant: ROHM Co., LTD., Kyoto (JP)

(72) Inventor: Toshimi Yamada, Kyoto (JP)

(21) Appl. No.: 19/647,754

(22) Filed: Apr. 14, 2026

(30) Foreign Application Priority Data
Apr. 25, 2025 (JP) 2025-073142

(51) Int. Cl. G01R 19/165; G01R 15/04

(52) U.S. Cl. CPC G01R 19/16576; G01R 15/04

(57) ABSTRACT

Provided is a voltage change detection circuit for detecting that a power supply voltage crosses a threshold value. The circuit includes a voltage dividing section that outputs each of a first voltage obtained by dividing a voltage between the power supply voltage and a predetermined potential at a first voltage dividing ratio and a second voltage obtained by dividing a voltage between the power supply voltage and a predetermined potential at a second voltage dividing ratio, and a comparator that compares the first voltage with a voltage obtained by adding an offset voltage based on the threshold value to the second voltage. A result of comparison by the comparator is output as a detection output signal indicating whether or not the power supply voltage crosses the threshold value.

### PRIORITY

The present disclosure contains subject matter related to that disclosed in Japanese Priority Patent Application JP 2025-073142 filed in the Japan Patent Office on Apr. 25, 2025, the entire content of which is hereby incorporated by reference.

### SUMMARY

The present disclosure relates to a voltage change detection circuit.

In an on-vehicle display driver integrated circuit (IC), for example, power supply abnormality is detected as one of functional safety measures. As a circuit for detecting voltage variations, a voltage variation detection circuit that compares a threshold voltage generated on the basis of a reference voltage with a voltage to be detected and detects voltage variations on the basis of the magnitude of the comparison result has been proposed (for example, Japanese Patent Laid-open No. 2018-96754).

In a detection circuit according to the existing technology described above, as a threshold voltage used for comparison, a reference voltage independent of a voltage to be detected is required. Accordingly, in a case where the voltage to be detected is a power supply voltage, a reference voltage independent of the power supply voltage is required, so that there is a problem that the layout area is significantly increased in order for such a reference voltage to be generated in the IC.

According to an embodiment of the present disclosure, there is provided a voltage change detection circuit for detecting that a power supply voltage crosses a threshold value. The voltage change detection circuit includes a voltage dividing section that outputs each of a first voltage obtained by dividing a voltage between the power supply voltage and a predetermined potential at a first voltage dividing ratio and a second voltage obtained by dividing a voltage between the power supply voltage and a predetermined potential at a second voltage dividing ratio, and a comparator that compares the first voltage with a voltage obtained by adding an offset voltage based on the threshold value to the second voltage. A result of comparison by the comparator is output as a detection output signal indicating whether or not the power supply voltage crosses the threshold value.

### BRIEF DESCRIPTION OF THE DRAWINGS

FIG. 1 is a circuit diagram for depicting a configuration of a voltage change detection circuit according to a first embodiment of the present disclosure;

FIG. 2 is a circuit diagram for depicting a configuration of a comparator in the first embodiment;

FIG. 3 is a diagram for depicting a relation between a change in a power supply voltage and a difference between input voltages of the comparator;

FIG. 4 is a diagram for depicting a relation between a change in the power supply voltage and a change in an output signal in the first embodiment;

FIG. 5 is a circuit diagram for depicting a configuration of a voltage change detection circuit according to a second embodiment of the present disclosure;

FIG. 6 is a circuit diagram for depicting a configuration of a comparator in the second embodiment;

FIG. 7 is a diagram for depicting a relation between a change in a power supply voltage and changes in output signals in the second embodiment;

FIG. 8 is a circuit diagram for depicting a configuration of a comparator in a third embodiment;

FIG. 9 is a diagram for depicting a relation between a change in a power supply voltage and a change in an output signal in the third embodiment;

FIG. 10 is a circuit diagram for depicting a configuration of a comparator in a fourth embodiment;

FIG. 11 is a circuit diagram for depicting a configuration of a comparator in a modified example of the first embodiment; and

FIG. 12 is a diagram for depicting a relation between a change in a power supply voltage and a change in an output signal in the modified example of the first embodiment.

### DETAILED DESCRIPTION

Preferred embodiments of the present disclosure will be described in detail below. It should be noted that, in the following description of the embodiments and the accompanying drawings, substantially the same or equivalent parts are denoted by the same reference signs.

### First Embodiment

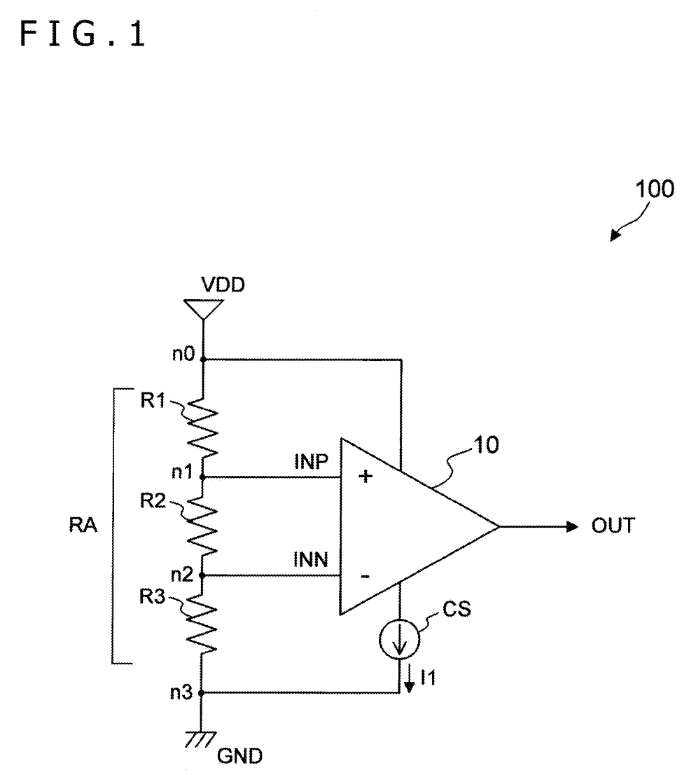

FIG. 1 is a circuit diagram for depicting a configuration of a voltage change detection circuit 100 according to a first embodiment of the present disclosure. The voltage change detection circuit 100 is a voltage drop detection circuit for detecting that a power supply voltage drops below a predetermined threshold value (hereinafter, also referred to as a drop in the power supply voltage). The voltage change detection circuit 100 includes a comparator 10, a resistor string RA, and a constant current source CS.

The resistor string RA includes resistors R1, R2, and R3 connected in series between a voltage supply line of a power supply voltage VDD and a supply line of a ground potential GND as a predetermined potential. The resistor string RA is a voltage dividing section that outputs a plurality of voltages (a first voltage and a second voltage) by dividing the power supply voltage VDD at different voltage division ratios (in the present embodiment, resistance ratios). In the following description, a resistance value of the resistor R1 is also referred to as R1, a resistance value of a resistor R2 is also referred to as R2, a resistance value of the resistor R3 is also referred to as R3, and a resistance value of the entire resistor string RA is also referred to as RA (= R1 + R2 + R3).

The power supply voltage VDD is applied to one end of the resistor R1. The one end of the resistor R1 is connected to the voltage supply line of the power supply voltage VDD via a node n0. One end of the resistor R2 is connected to the other end of the resistor R1 via a node n1. The other end of the resistor R2 is connected to one end of the resistor R3 via a node n2. The other end of the resistor R3 is grounded (that is, connected to the supply line of the ground potential GND) via a node n3.

A first input terminal that is a positive-side voltage input terminal of the comparator 10 is connected to the node n1 between the resistors R1 and R2. As a positive-side input voltage INP of the comparator 10, VDD × (R2 + R3)/RA, which is the first voltage obtained by dividing the power supply voltage VDD at the position of the node n1, is input.

A second input terminal that is a negative-side voltage input terminal of the comparator 10 is connected to the node n2 between the resistors R2 and R3. As a negative-side input voltage INN of the comparator 10, VDD × R3/RA, which is the second voltage obtained by dividing the power supply voltage VDD at the position of the node n2, is input.

The comparator 10 outputs a detection output signal OUT having a signal level of a logic level 1 (H level) or a logic level 0 (L level) on the basis of the voltages input to the first input terminal and the second input terminal.

A positive-side power supply terminal of the comparator 10 is connected to the node n0 between the one end of the resistor R1 and the voltage supply line of the power supply voltage VDD. A negative-side power supply terminal of the comparator 10 is connected to the node n3 between the resistor R3 and the supply line of the ground potential GND via the constant current source CS. The constant current source CS sends a constant current I1 from the negative-side power supply terminal of the comparator 10 toward the supply line of the ground potential GND.

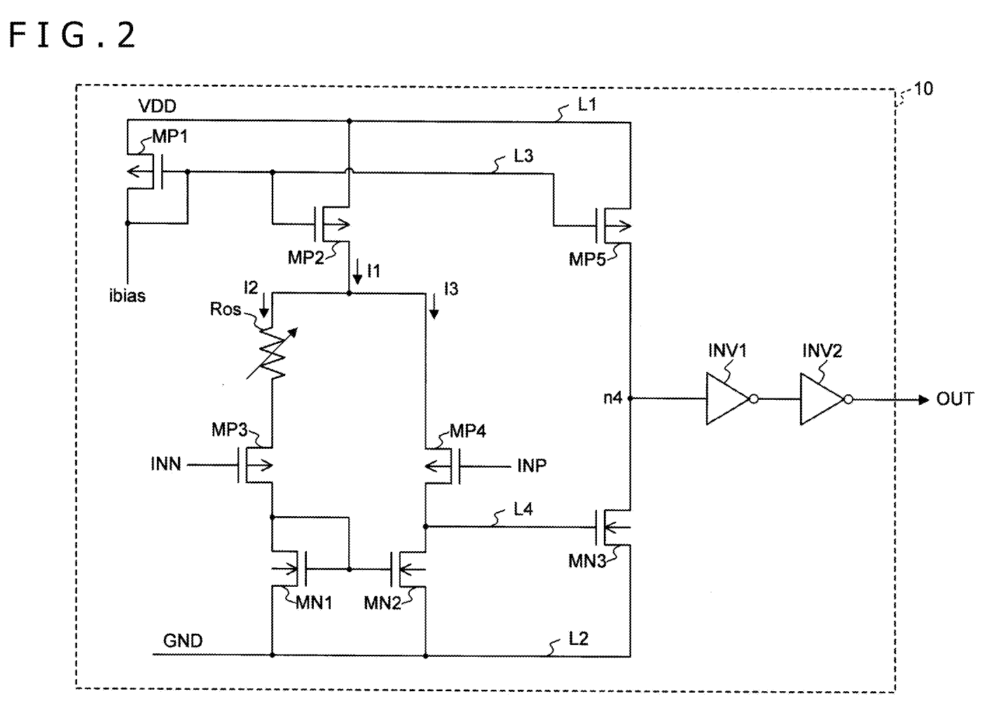

FIG. 2 is a circuit diagram for depicting a configuration of the comparator 10 of the present embodiment. The comparator 10 includes transistors MP1, MP2, MP3, MP4, and MP5, transistors MN1, MN2, and MN3, a variable resistor Ros, and inverters INV1 and INV2.

The transistor MP1 includes a P-channel metal-oxide-semiconductor field-effect transistor (MOSFET) that is a first conductive-type transistor. A source of the transistor MP1 is connected to a line L1 that is the voltage supply line of the power supply voltage VDD. A gate and a drain of the transistor MP1 are connected to each other and to a line L3.

The transistor MP2 includes a P-channel MOSFET. A source of the transistor MP2 is connected to the line L1, and a gate thereof is connected to the line L3.

The variable resistor Ros is a variable resistor device configured to have a variable resistance value. One end of the variable resistor Ros is connected to a drain of the transistor MP2.

The transistor MP3 includes a P-channel MOSFET. A source of the transistor MP3 is connected to the other end of the variable resistor Ros. The positive-side input voltage INP is applied to a gate of the transistor MP3.

The transistor MP4 is a transistor constituting a differential pair in the comparator 10 together with the transistor MP3, and includes a P-channel MOSFET. A source of the transistor MP4 is connected to the drain of the transistor MP2. The negative-side input voltage INN is applied to a gate of the transistor MP4. A drain of the transistor MP4 is connected to a line L4.

The transistor MN1 includes an N-channel MOSFET that is a second conductive-type transistor. A source of the transistor MN1 is connected to a line L2 that is the supply line of the ground potential GND. A drain and a gate of the transistor MN1 are connected to each other and to a drain of the transistor MP3.

The transistor MN2 includes an N-channel MOSFET. A source of the transistor MN2 is connected to the line L2. A drain of the transistor MN2 is connected to the line L4. A gate of the transistor MN2 is connected to the gate and the drain of the transistor MN1 and to the drain of the MP3.

The transistor MP5 includes a P-channel MOSFET. A source of the transistor MP5 is connected to the line L1. A gate of the transistor MP5 is connected to the line L3. A drain of the transistor MP5 is connected to a node n4.

The transistor MN3 includes an N-channel MOSFET. A source of the transistor MN3 is connected to the line L2. A gate of the transistor MN3 is connected to the drains of the transistor MP4 and the transistor MN2 via the line L4. A drain of the transistor MN3 is connected to the node n4.

An input terminal of the inverter INV1 is connected to the node n4. The inverter INV1 outputs a voltage obtained by inverting a potential of the node n4.

An input terminal of the inverter INV2 is connected to an output terminal of the inverter INV1. The inverter INV2 outputs a voltage obtained by inverting a voltage input to the input terminal as the detection output signal OUT.

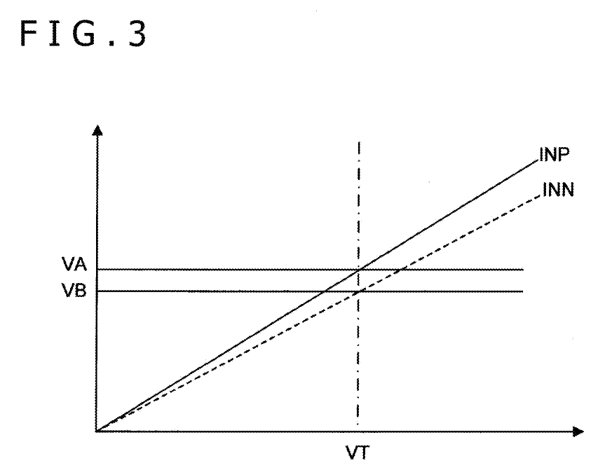

FIG. 3 is a diagram for depicting changes in the positive-side input voltage INP and the negative-side input voltage INN according to changes in the power supply voltage VDD. As the power supply voltage VDD drops, the difference (hereinafter, referred to as a differential voltage) between the positive-side input voltage INP and the negative-side input voltage INN becomes smaller.

Assuming that a voltage level used as a determination threshold value for detecting a drop in the voltage level of the power supply voltage VDD by the voltage change detection circuit 100 of the present embodiment is a determination threshold voltage VTH, as depicted in FIG. 3, when VDD = VTH, the positive-side input voltage INP is at a voltage level VA, the negative-side input voltage INN is at a voltage level VB, and a differential voltage VDF between the positive-side input voltage INP and the negative-side input voltage INN is VDF = (VA − VB).

As described above, as the power supply voltage VDD drops, the differential voltage between the positive-side input voltage INP and the negative-side input voltage INN becomes smaller, so that it can be determined whether or not the power supply voltage VDD has dropped below the determination threshold voltage VTH by comparing a voltage obtained by adding the above voltage (VA − VB) to the negative-side input voltage INN with the positive-side input voltage INP.

As described above, the variable resistor Ros is inserted between the drain of the transistor MP2 and the source of the transistor MP3. In the comparator 10 of the present embodiment, the voltage across the variable resistor Ros is added to the negative-side input voltage INN as an offset voltage, and the resultant voltage is compared with the positive-side input voltage INP. Thus, by setting the resistance value of the variable resistor Ros such that the voltage across the variable resistor Ros becomes the above voltage (VA − VB), it can be determined whether or not the power supply voltage VDD has dropped below the determination threshold voltage VTH.

Specifically, in the case of INP ≥ INN + (VA − VB), the comparator 10 outputs the detection output signal OUT of the H level. Accordingly, it is determined that the power supply voltage VDD is not lower than the determination threshold voltage VTH, that is, a voltage drop of a predetermined amount or more has not occurred.

On the other hand, in the case of INP < INN + (VA − VB), the comparator 10 outputs the detection output signal OUT of the L level. Accordingly, it is determined that the power supply voltage VDD is lower than the determination threshold voltage VTH, that is, a voltage drop of a predetermined amount or more has occurred.

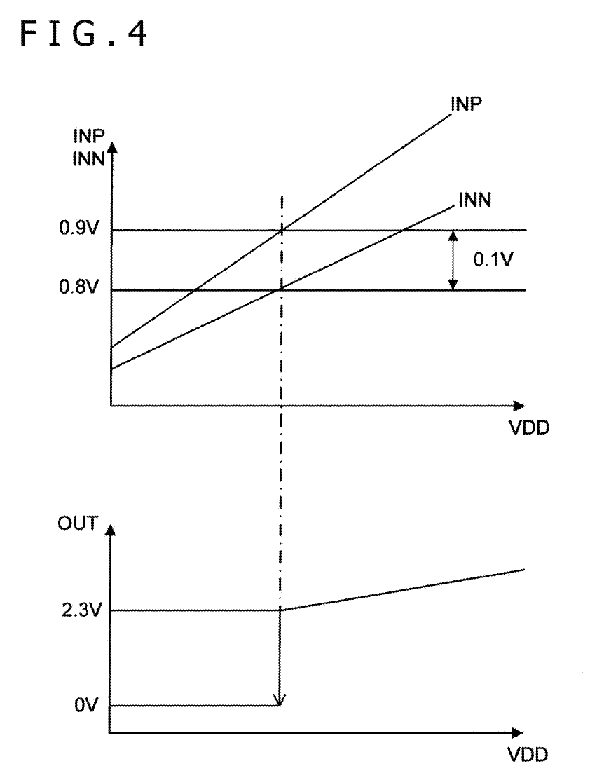

FIG. 4 is a diagram for depicting an example of a relation between a change in the power supply voltage VDD and a change in the signal level of the detection output signal OUT of the comparator 10 in the present embodiment.

For example, when the determination threshold voltage VTH = 2.3 V, R1 = 140 kΩ, R2 = 10 kΩ, and R3 = 80 kΩ, the positive-side input voltage INP, that is, the voltage level VA, when the power supply voltage VDD = 2.3 V is 0.9 V. In addition, the negative-side input voltage INN, that is, the voltage level VB, when the power supply voltage VDD = 2.3 V is 0.8 V. Accordingly, VA − VB = 0.1 V is satisfied.

In the configuration of the comparator 10 of the present embodiment, the polarity of the detection output signal OUT of the comparator 10 changes when a current I2 flowing through the transistor MP3 and a current I3 flowing through the transistor MP4 have the same current value, that is, when the currents I2 and I3 are 1/2 of the current I1. Therefore, the resistance value of Ros is set (that is, offset adjustment is performed on the resistance value of Ros) such that I1 × (1/2) × Ros = 0.1 V is satisfied.

In a case where the power supply voltage VDD is equal to or larger than 2.3 V, INP ≥ INN + I2 × Ros is satisfied, and thus, the detection output signal OUT of the comparator 10 is at the H level. On the other hand, when the power supply voltage VDD drops below 2.3 V, INP < INN + I2 × Ros is satisfied, and thus, the detection output signal OUT of the comparator 10 is at the L level. Accordingly, on the basis of the signal level of the detection output signal OUT, it can be detected that the power supply voltage VDD has dropped below the determination threshold voltage VTH = 2.3 V.

As described above, in the voltage change detection circuit 100 of the present embodiment, the voltage drop of the power supply voltage VDD is detected by inputting, to the comparator 10, the first voltage obtained by the resistance division between the power supply voltage VDD and the ground potential GND as the positive-side input voltage INP and the second voltage as the negative-side input voltage INN, and comparing the voltage obtained by adding the offset voltage set according to the level of the determination threshold voltage VTH used for determining the voltage drop to the negative-side input voltage INN with the positive-side input voltage INP.

According to such a configuration, since it is not necessary to generate a reference voltage independent of the power supply voltage VDD, the voltage drop of the power supply voltage VDD can be detected without a circuit for generating the reference voltage being provided in the IC.

Thus, according to the voltage change detection circuit 100 of the present embodiment, it is possible to detect a drop in the power supply voltage while suppressing an increase in the circuit scale.

### Second Embodiment

Next, a second embodiment of the present disclosure will be described.

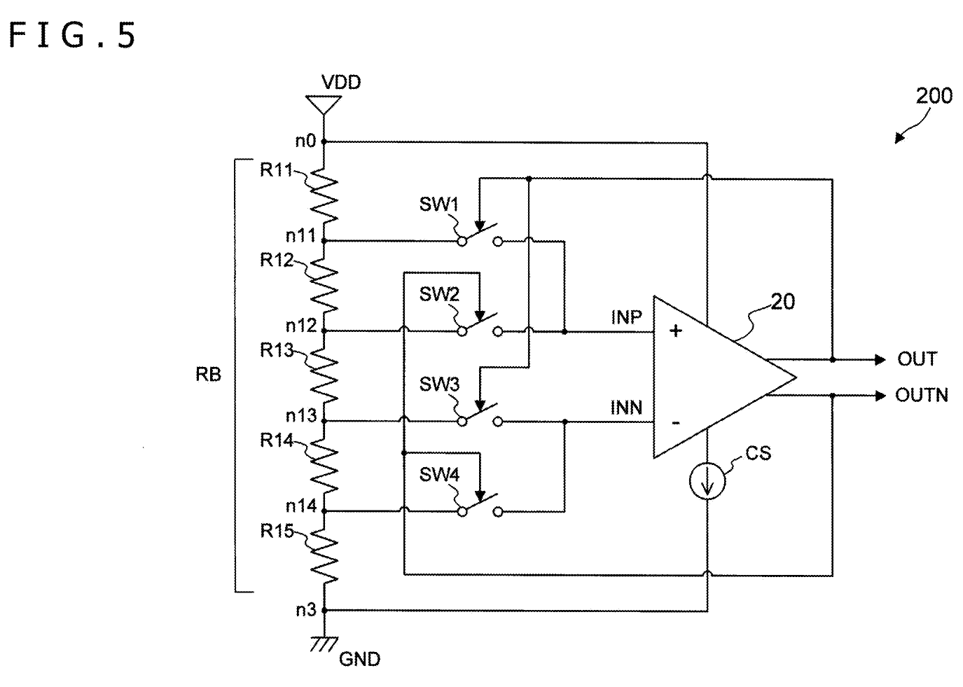

FIG. 5 is a circuit diagram for depicting a configuration of a voltage change detection circuit 200 according to the second embodiment of the present disclosure. The voltage change detection circuit 200 includes a comparator 20, a resistor string RB, a constant current source CS, and switch groups SW1 to SW4.

The resistor string RB includes resistors R11, R12, R13, R14, and R15 connected in series between a voltage supply line of a power supply voltage VDD and a supply line of a ground potential GND. In the following description, a resistance value of the resistor R11 is also referred to as R11, a resistance value of the resistor R12 is also referred to as R12, a resistance value of the resistor R13 is also referred to as R13, a resistance value of the resistor R14 is also referred to as R14, and a resistance value of the resistor R15 is also referred to as R15. In addition, a resistance value of the entire resistor string RB is also referred to as RB (= R11 + R12 + R13 + R14 + R15).

One end of the resistor R11 is connected to the voltage supply line of the power supply voltage VDD via a node n0. One end of the resistor R12 is connected to the other end of the resistor R11 via a node n11. One end of the resistor R13 is connected to the other end of the resistor R12 via a node n12. One end of the resistor R14 is connected to the other end of the resistor R13 via a node n13. One end of the resistor R15 is connected to the other end of the resistor R14 via a node n14. The other end of the resistor R15 is grounded (that is, connected to the supply line of the ground potential GND) via a node n3.

One end of the switch SW1 is connected to the node n11 between the resistors R11 and R12, and the other end thereof is connected to a first input terminal that is a positive-side voltage input terminal of the comparator 20. When the switch SW1 is turned on, the node n11 is connected to the first input terminal of the comparator 20, and a voltage of the node n11 is input to the comparator 20 as a positive-side input voltage INP. The switch SW1 is controlled to be turned on and off in response to a detection output signal OUT output from a first output terminal of the comparator 20. In the present embodiment, the switch SW1 is turned on in a case where the detection output signal OUT is at the H level, and is turned off in a case where the detection output signal OUT is at the L level.

One end of the switch SW2 is connected to the node n12 between the resistors R12 and R13, and the other end thereof is connected to the first input terminal that is the positive-side voltage input terminal of the comparator 20. When the switch SW2 is turned on, the node n12 is connected to the first input terminal of the comparator 20, and a voltage of the node n12 is input to the comparator 20 as the positive-side input voltage INP. The switch SW2 is controlled to be turned on and off in response to a detection output signal OUTN output from a second output terminal of the comparator 20. In the present embodiment, the switch SW2 is turned on in a case where the detection output signal OUTN is at the H level, and is turned off in a case where the detection output signal OUTN is at the L level.

One end of the switch SW3 is connected to the node n13 between the resistors R13 and R14, and the other end thereof is connected to a second input terminal that is a negative-side voltage input terminal of the comparator 20. When the switch SW3 is turned on, the node n13 is connected to the second input terminal of the comparator 20, and a voltage of the node n13 is input to the comparator 20 as a negative-side input voltage INN. The switch SW3 is controlled to be turned on and off in response to the detection output signal OUT output from the first output terminal of the comparator 20. In the present embodiment, the switch SW3 is turned on in the case where the detection output signal OUT is at the H level, and is turned off in the case where the detection output signal OUT is at the L level.

One end of the switch SW4 is connected to the node n14 between the resistors R14 and R15, and the other end thereof is connected to the second input terminal that is the negative-side voltage input terminal of the comparator 20. When the switch SW4 is turned on, the node n14 is connected to the second input terminal of the comparator 20, and a voltage of the node n14 is input to the comparator 20 as the negative-side input voltage INN. The switch SW4 is controlled to be turned on and off in response to the detection output signal OUTN output from the second output terminal of the comparator 20. In the present embodiment, the switch SW4 is turned on in the case where the detection output signal OUTN is at the H level, and is turned off in the case where the detection output signal OUTN is at the L level.

The first input terminal that is the positive-side voltage input terminal of the comparator 20 is connected to the other end of the switch SW1 and the other end of the switch SW2. As described above, the switch SW1 is a switch controlled to be turned on and off in response to the detection output signal OUT, and the switch SW2 is a switch controlled to be turned on and off in response to the detection output signal OUTN. That is, the switches SW1 and SW2 are complementarily turned on and off. Thus, the first input terminal of the comparator 20 is selectively connected to either the node n11 or the node n12.

When the switch SW1 is on and the switch SW2 is off, the first input terminal of the comparator 20 is connected to the node n11, and VDD × (R12 + R13 + R14 + R15)/RB, which is a voltage obtained by dividing the power supply voltage VDD at the position of the node n11, is input as the positive-side input voltage INP. On the other hand, when the switch SW1 is off and the switch SW2 is on, the first input terminal of the comparator 20 is connected to the node n12, and VDD × (R13 + R14 + R15)/RB, which is a voltage obtained by dividing the power supply voltage VDD at the position of the node n12, is input as the positive-side input voltage INP.

The second input terminal that is the negative-side voltage input terminal of the comparator 20 is connected to the other end of the switch SW3 and the other end of the switch SW4. The switches SW3 and SW4 are switches controlled to be turned on and off in response to the detection output signal OUT and the detection output signal OUTN, respectively, and are complementarily turned on and off. Thus, the second input terminal of the comparator 20 is selectively connected to either the node n13 or the node n14.

When the switch SW3 is on and the switch SW4 is off, the second input terminal of the comparator 20 is connected to the node n13, and VDD × (R14 + R15)/RB, which is a voltage obtained by dividing the power supply voltage VDD at the position of the node n13, is input as the negative-side input voltage INN. On the other hand, when the switch SW3 is off and the switch SW4 is on, the second input terminal of the comparator 20 is connected to the node n14, and VDD × R15/RB, which is a voltage obtained by dividing the power supply voltage VDD at the position of the node n14, is input as the negative-side input voltage INN.

The comparator 20 outputs the detection output signal OUT having a signal level of a logic level 1 (H level) or a logic level 0 (L level) from the first output terminal on the basis of the voltages input to the first input terminal and the second input terminal. In addition, the comparator 20 outputs, from the second output terminal, the detection output signal OUTN obtained by inverting the detection output signal OUT.

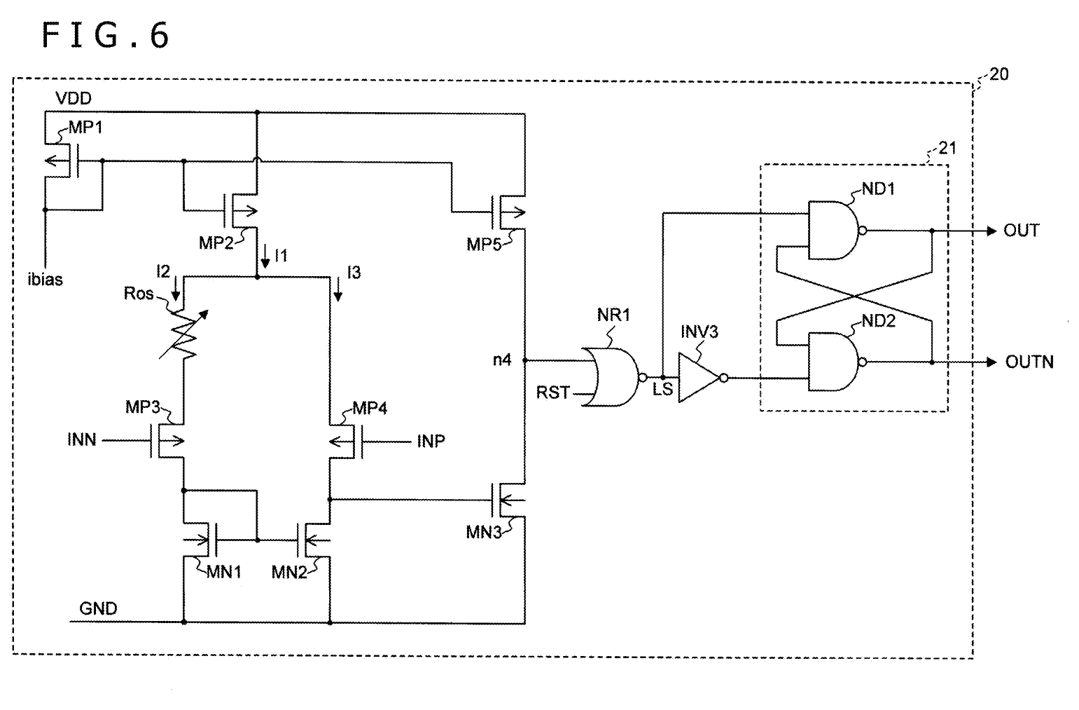

FIG. 6 is a circuit diagram for depicting a configuration of the comparator 20 of the present embodiment. As with the comparator 10 of the first embodiment, the comparator 20 includes transistors MP1, MP2, MP3, MP4, and MP5, transistors MN1, MN2, and MN3, and a variable resistor Ros. In addition, the comparator 20 includes a NOR gate NR1, an inverter INV3, and an RS latch circuit 21.

The NOR gate NR1 is a logic gate circuit for outputting a logic operation signal LS that is a signal obtained by performing a logic operation of a NOR on a signal input to each of a first input terminal and a second input terminal. The first input terminal of the NOR gate NR1 is connected to a node n4. A reset signal RST is input to the second input terminal of the NOR gate NR1. The reset signal RST is a signal for bringing the operation of the IC including the voltage change detection circuit 200 to an initial state by changing the signal level from the L level (logic level 0) to the H level (logic level 1), and is, for example, a power-on reset signal supplied from the outside of the voltage change detection circuit 200 immediately after the power of the IC including the voltage change detection circuit 200 is turned on.

An input terminal of the inverter INV3 is connected to an output terminal of the NOR gate NR1. The inverter INV3 outputs, from an output terminal thereof, a signal obtained by inverting the signal level of the logic operation signal LS input to the input terminal.

The RS latch circuit 21 includes a NAND gate ND1 and a NAND gate ND2. Each of the NAND gates ND1 and ND2 is a logic gate circuit for outputting the NAND of the signals input to a first input terminal and a second input terminal.

The first input terminal of the NAND gate ND1 is connected to a node between the output terminal of the NOR gate NR1 and the input terminal of the inverter INV3. The second input terminal of the NAND gate ND1 is connected to an output terminal of the NAND gate ND2. The first input terminal of the NAND gate ND2 is connected to an output terminal of the NAND gate ND1. The second input terminal of the NAND gate ND2 is connected to an output terminal of the inverter INV3. The detection output signal OUT is output from the output terminal of the NAND gate ND1. The detection output signal OUTN is output from the output terminal of the NAND gate ND2.

In the voltage change detection circuit 200 of the present embodiment, a first determination threshold voltage VTD and a second determination threshold voltage VTR are set on the basis of the resistance values of the resistors R11 to R15, and a voltage drop is detected. Specifically, in a case where the power supply voltage VDD changes from a state of being equal to or larger than the first determination threshold voltage VTD to a state of being smaller than the first determination threshold voltage VTD, it is determined that the power supply voltage VDD has dropped. In addition, in a case where a state in which it is determined that the power supply voltage VDD has dropped changes to a state in which the power supply voltage VDD is equal to or larger than the second determination threshold voltage VTR, it is determined that the power supply voltage VDD has recovered from the voltage drop state (hereinafter, also referred to as release of the voltage drop). This determination operation will be described below.

First, after the power is turned on, when the reset signal RST changes from the L level to the H level, the detection output signal OUT is at the H level, and the detection output signal OUTN is at the L level. Accordingly, the switches SW1 and SW3 are turned on, and the switches SW2 and SW4 are turned off.

In a case where the power supply voltage VDD is equal to or larger than the first determination threshold voltage VTD, the detection output signal OUT is at the H level, the detection output signal OUTN is at the L level, and the switches SW1 to SW4 are maintained in the state immediately after the power is turned on.

When the power supply voltage VDD drops below the first determination threshold voltage VTD, the detection output signal OUT changes from the H level to the L level, and the detection output signal OUTN changes from the L level to the H level. Accordingly, the switches SW1 and SW3 are turned off, and the switches SW2 and SW4 are turned on.

At this time, the positive-side input voltage INP = VDD × (R13 + R14 + R15)/RB and the negative-side input voltage INN = VDD × R15/RB are satisfied, and the voltage difference between the positive-side input voltage INP and the negative-side input voltage INN is VDD × (R13 + R14)/RB.

In performing such a determination operation (detection operation of the voltage drop), hysteresis can be provided in the detection of the voltage drop by setting the resistance values of the resistors R11 to R15 such that the positive-side input voltage INP and the negative-side input voltage INN obtained when the power supply voltage VDD is the first determination threshold voltage VTD are equal to the positive-side input voltage INP and the negative-side input voltage INN obtained when the power supply voltage VDD is the second determination threshold voltage VTR. Specifically, the resistance values of the resistors R12, R13, R14, and R15 may be set such that VTD/VTR = (R13 + R14)/(R12 + R13) is satisfied.

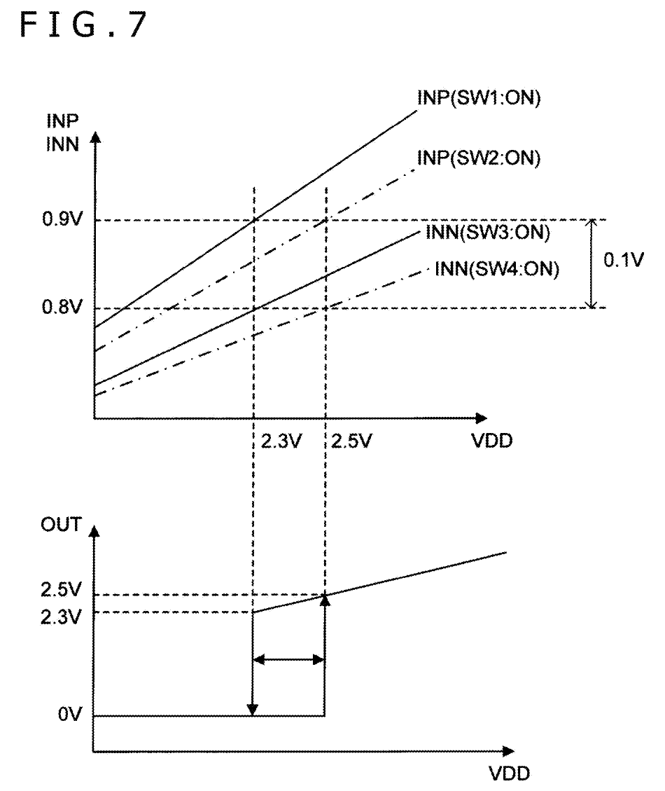

FIG. 7 is a diagram for depicting an example of a relation between a change in the power supply voltage VDD and changes in the signal levels of the detection output signals OUT and OUTN of the comparator 20 in the present embodiment.

For example, when the first determination threshold voltage VTD = 2.3 V and the second determination threshold voltage VTR = 2.5 V, RB = 230 kΩ is satisfied by setting R11 = 140 kΩ, R12 = 7.2 kΩ, R13 = 2.8 kΩ, R14 = 6.4 kΩ, and R15 = 73.6 kΩ.

When the power supply voltage VDD = the first determination threshold voltage VTD = 2.3 V, the positive-side input voltage INP = 2.3 V × (90 kΩ/230 kΩ) = 0.9 V and the negative-side input voltage INN = 2.3 V × (80 kΩ/230 kΩ) = 0.8 V are satisfied.

When the power supply voltage VDD = the second determination threshold voltage VTR = 2.5 V, the positive-side input voltage INP = 2.5 V × (82.8 kΩ/230 kΩ) = 0.9 V and the negative-side input voltage INN = 2.5 V × (73.6 kΩ/230 kΩ) = 0.8 V are satisfied.

By setting the resistance values of the resistors R11 to R15 as described above, the positive-side input voltage INP and the negative-side input voltage INN obtained at the time of detecting the voltage drop and the positive-side input voltage INP and the negative-side input voltage INN obtained at the time of releasing the voltage drop have the same voltage values, and thus, hysteresis can be provided in the detection and release of the voltage drop as depicted in the lower part of FIG. 7.

Thus, according to the voltage change detection circuit 200 of the present embodiment, the occurrence of chattering of the comparator output at the time of detecting the voltage drop can be prevented.

### Third Embodiment

Next, a third embodiment of the present disclosure will be described. A voltage change detection circuit of the present embodiment is an overvoltage detection circuit for detecting that the power supply voltage rises above a predetermined threshold value (hereinafter, also referred to as an overvoltage of the power supply voltage), and differs from the voltage change detection circuit 200 of the second embodiment in the configuration of the comparator.

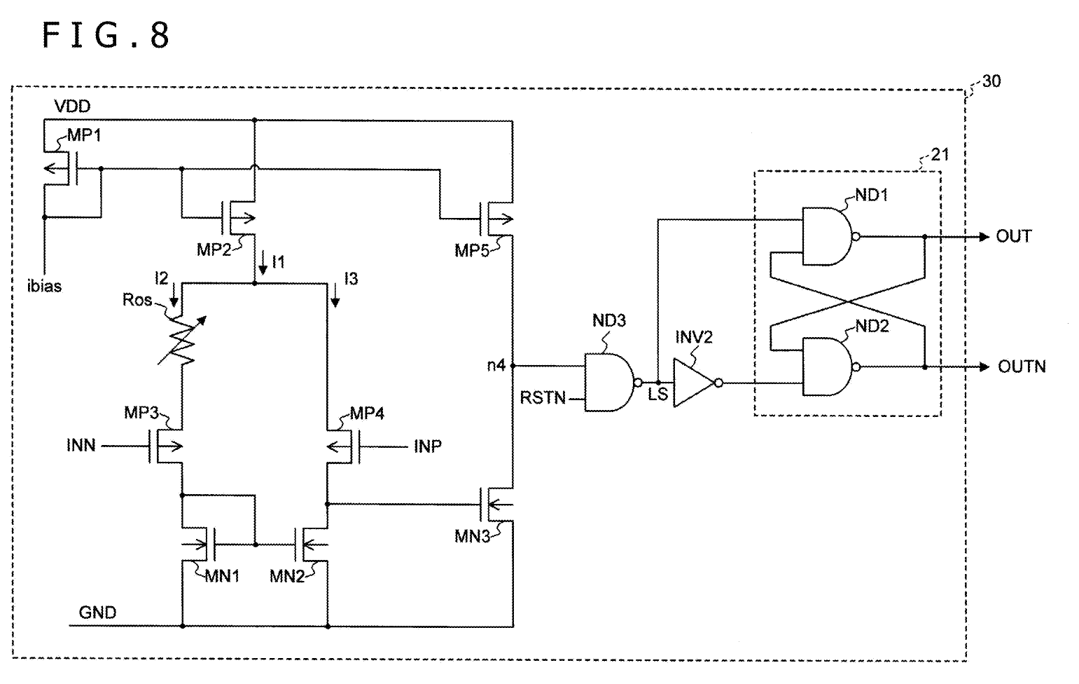

FIG. 8 is a circuit diagram for depicting a configuration of a comparator 30 of the present embodiment. The comparator 30 has a NAND gate ND3 instead of the NOR gate NR1 in the comparator 20 of the second embodiment.

The NAND gate ND3 is a logic gate circuit for outputting a logic operation signal LS that is a signal obtained by performing a logic operation of a NAND on the signal input to each of a first input terminal and a second input terminal. The first input terminal of the NAND gate ND3 is connected to a node n4. An inverted reset signal RSTN that is a signal obtained by inverting a reset signal RST is input to the second input terminal of the NAND gate ND3.

In the voltage change detection circuit of the present embodiment, a first determination threshold voltage VTDA and a second determination threshold voltage VTRA for detecting the overvoltage are set on the basis of resistance values of resistors R11 to R15, and the overvoltage is detected. Specifically, in a case where a power supply voltage VDD changes from a state of being smaller than the first determination threshold voltage VTDA to a state of being equal to or larger than the first determination threshold voltage VTDA, it is determined that the power supply voltage VDD is an overvoltage. In addition, in a case where a state in which it is determined that the power supply voltage VDD is an overvoltage changes to a state in which the power supply voltage VDD is smaller than the second determination threshold voltage VTRA, it is determined that the power supply voltage VDD has recovered from the overvoltage state (hereinafter, also referred to as release of the overvoltage). This determination operation will be described below.

First, after the power is turned on, when the inverted reset signal RSTN changes from the H level to the L level according to the change of the reset signal RST from the L level to the H level, a detection output signal OUT is at the L level, and a detection output signal OUTN is at the H level. Accordingly, switches SW1 and SW3 are turned off, and switches SW2 and SW4 are turned on.

In a case where the power supply voltage VDD is smaller than the first determination threshold voltage VTDA, since INP < INN + Ros × I2 is satisfied, the detection output signal OUT is at the L level, the detection output signal OUTN is at the H level, and the switches SW1 to SW4 are maintained in the state immediately after the power is turned on.

When the power supply voltage VDD rises to be equal to or larger than the first determination threshold voltage VTDA, since INP ≥ INN + Ros × I2 is satisfied, the detection output signal OUT changes from the L level to the H level, and the detection output signal OUTN changes from the H level to the L level. Accordingly, the switches SW1 and SW3 are turned on, and the switches SW2 and SW4 are turned off.

Thereafter, the state in which the detection output signal OUT is at the H level and the detection output signal OUTN is at the L level is maintained until the voltage level of the power supply voltage VDD becomes the second determination threshold voltage VTRA. When the voltage level of the power supply voltage VDD drops to the second determination threshold voltage VTRA, since INP < INN + Ros × I2 is satisfied, the detection output signal OUT is at the L level, and the detection output signal OUTN is at the H level. Accordingly, the switches SW1 and SW3 are turned off, and the switches SW2 and SW4 are turned on.

In performing such a determination operation (detection operation of the voltage drop), hysteresis can be provided in the detection of the voltage drop by setting the resistance values of the resistors R11 to R15 such that the positive-side input voltage INP and the negative-side input voltage INN obtained when the power supply voltage VDD is the first determination threshold voltage VTDA are equal to the positive-side input voltage INP and the negative-side input voltage INN obtained when the power supply voltage VDD is the second determination threshold voltage VTRA. Specifically, the resistance values of the resistors R12, R13, R14, and R15 may be set such that VTDA/VTRA = (R12 + R13)/(R13 + R14) is satisfied.

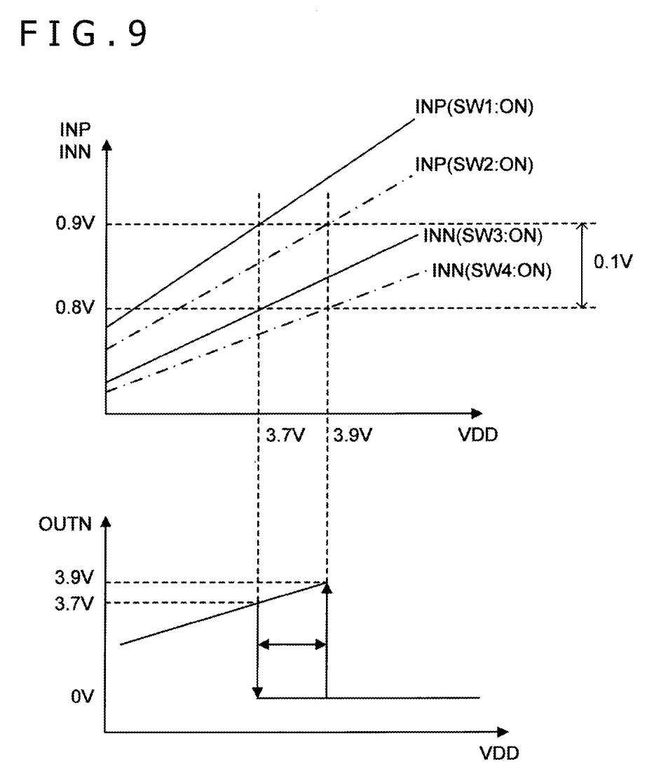

FIG. 9 is a diagram for depicting an example of a relation between a change in the power supply voltage VDD and a change in the signal level of OUTN of the comparator 30 in the present embodiment.

For example, when the first determination threshold voltage VTDA = 3.9 V and the second determination threshold voltage VTRA = 3.7 V, RB = 370 kΩ is satisfied by setting R11 = 280 kΩ, R12 = 4.62 kΩ, R13 = 5.38 kΩ, R14 = 4.1 kΩ, and R15 = 75.9 kΩ.

When the power supply voltage VDD = the first determination threshold voltage VTDA = 3.9 V, the positive-side input voltage INP = 3.9 V × (85.38 kΩ/370 kΩ) = 0.9 V and the negative-side input voltage INN = 3.9 V × (75.9 kΩ/370 kΩ) = 0.8 V are satisfied.

When the power supply voltage VDD = the second determination threshold voltage VTRA = 3.7 V, the positive-side input voltage INP = 3.7 V × (90 kΩ/370 kΩ) = 0.9 V and the negative-side input voltage INN = 3.7 V × (80 kΩ/370 kΩ) = 0.8 V are satisfied.

By setting the resistance values of the resistors R11 to R15 as described above, the positive-side input voltage INP and the negative-side input voltage INN obtained at the time of detecting the overvoltage and the positive-side input voltage INP and the negative-side input voltage INN obtained at the time of releasing the overvoltage have the same voltage values, and thus, hysteresis can be provided in the detection and release of the overvoltage as depicted in the lower part of FIG. 9.

As described above, according to the voltage change detection circuit having the comparator 30 of the present embodiment, it is possible to detect that the power supply voltage VDD becomes an overvoltage while preventing the occurrence of chattering of the comparator output.

### Fourth Embodiment

Next, a fourth embodiment of the present disclosure will be described. A voltage change detection circuit of the present embodiment has a basic configuration similar to that of the voltage change detection circuit 100 of the first embodiment, but differs from the voltage change detection circuit 100 of the first embodiment in the configuration of the comparator.

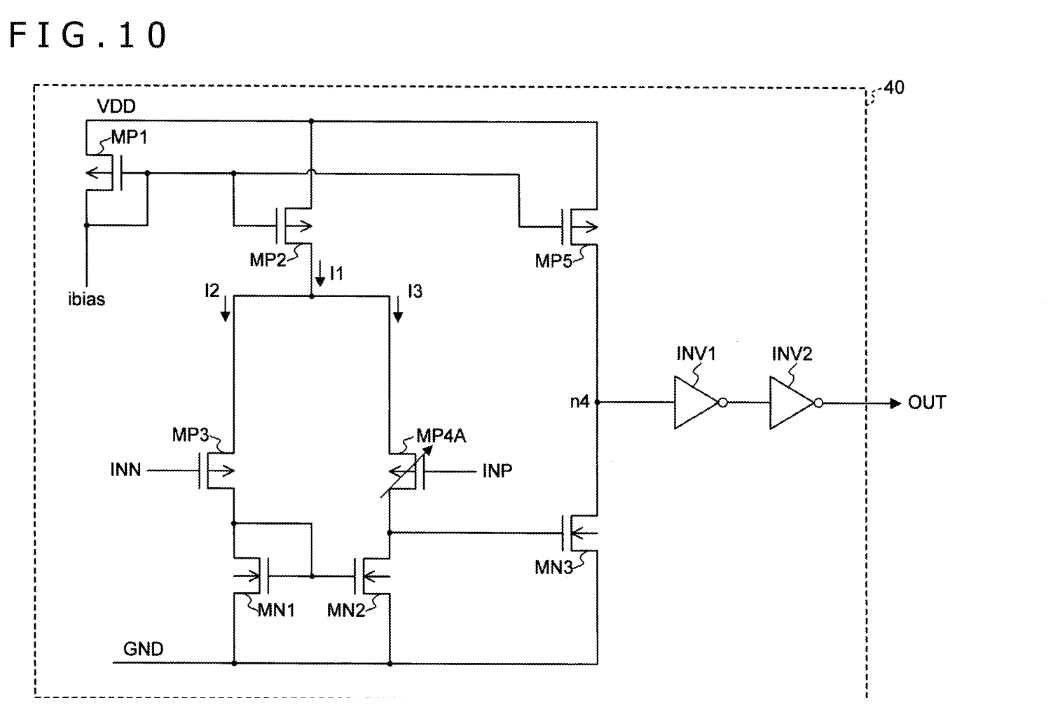

FIG. 10 is a circuit diagram for depicting a configuration of a comparator 40 of the present embodiment. The comparator 40 differs from the comparator 10 of the first embodiment in that the comparator 40 does not have the variable resistor Ros as in the comparator 10 of the first embodiment and a transistor MP4A whose size (for example, a gate width W) can be changed is provided instead of the transistor MP4.

The transistor MP4A includes, for example, a plurality of P-channel MOSFETs (the illustration thereof is omitted) connected in parallel, and the gate width W as a whole can be changed by switching the number of MOSFETs connected in parallel by a switch being turned on or off.

In the comparator 40 of the present embodiment, an offset voltage added to a negative-side input voltage INN is generated by setting a transistor MP3 and the transistor MP4A, which are transistors in the differential stage, to have different dimensions.

A current Imp3 flowing through the transistor MP3 can be expressed by Imp3 = (β1)/2 × (Vgs1 − Vt)2(1 + λVds1). On the other hand, a current Imp4 flowing through the transistor MP4A can be expressed by Imp4 = (β2)/2 × (Vgs2 − Vt)2(1 + λVds2).

Here, all of β1 = μn × Cox × W/L, gs1, and Vds1 in Imp3 are values of the transistor MP3. In addition, all of β2 = μn × Cox × W/L, gs2, and Vds2 in Imp4 are values of the transistor MP4A.

In a case where the gate-to-source voltage vgs1 of the transistor MP3 and the gate-to-source voltage vgs2 of the transistor MP4A are to have an offset, the gate width W of the transistor MP4 may be set such that (β1)/2 × (Vgs1 − Vt)2(1 + λVds1) = (β2)/2 × (Vgs2 − Vt)2(1 + λVds2), that is, (β1)/2 × (Vgs1 − Vt)2 = (β2)/2 × (Vgs2 − Vt)2 is established.

For example, as in the first embodiment, if the positive-side input voltage INP = 0.9 V and the negative-side input voltage INN = 0.8 V when the determination threshold voltage VTH = 2.3 V and the power supply voltage VDD = 2.3 V and if source voltages Vtail of the transistors MP3 and MP4A = 1.65 V when the threshold voltage Vt of the transistor MP3 = 0.65 V and the power supply voltage VDD = 2.3 V, β1 × (0.85 V − 0.65 V)2 = β2 × (0.85 V − 0.65 V)2 is satisfied, and β2 = β1 × 4 is satisfied.

Thus, if a gate lengths L of the transistor MP3 and the transistor MP4A are set to the same value and the gate width W of the transistor MP4A is set to be four times as long as the gate width W of the transistor MP3, the offset voltage similar to the first embodiment can be set.

As described above, according to the configuration of the comparator 40 of the present embodiment, the offset voltage is set by changing the gate width W of the transistor MP4, and the voltage obtained by adding the offset voltage to the negative-side input voltage INN is compared with the positive-side input voltage INP, so that it is possible to detect a voltage drop in the power supply voltage VDD.

It should be noted that the present disclosure is not limited to the embodiments described above. For example, the case where the voltage change detection circuit 100 is a voltage drop detection circuit has been described as an example in the first embodiment, but the present disclosure is not limited to this, and the voltage change detection circuit 100 may be configured as an overvoltage detection circuit for detecting a rise in the power supply voltage.

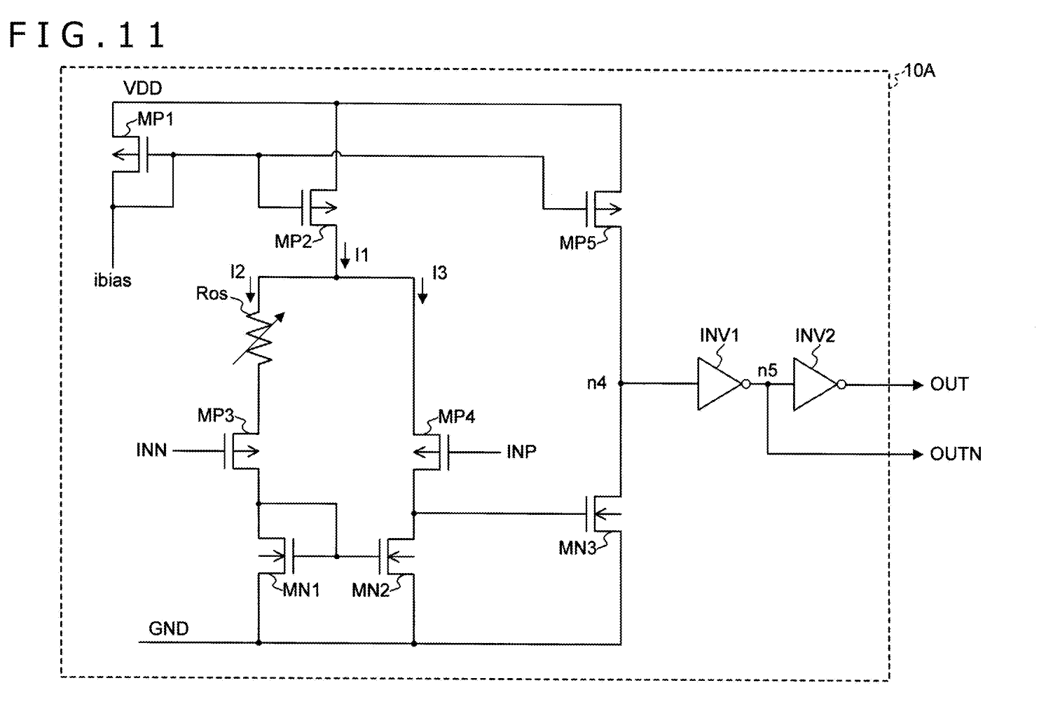

FIG. 11 is a circuit diagram for depicting a configuration of a comparator 10A according to such a modified example. In addition to the configuration of the comparator 10 of the first embodiment depicted in FIG. 2, a configuration of an output part for outputting a detection output signal OUTN is added.

The comparator 10A outputs the detection output signal OUTN from a node n5 between an output terminal of an inverter INV1 and an input terminal of an inverter INV2. The detection output signal OUTN is a signal obtained by inverting the signal level of a detection output signal OUT (to be precise, the signal obtained by inverting the detection output signal OUTN with the inverter INV2 is the detection output signal OUT).

In the comparator 10A having such a configuration, assuming that a determination threshold voltage VTH for detecting an overvoltage = 3.9 V, R1 = 300 kΩ, R2 = 10 kΩ, and R3 = 80 kΩ, a positive-side input voltage INP = 0.9 V and a negative-side input voltage INN = 0.8 V are satisfied when the power supply voltage VDD = 3.9 V. Since the polarity of the detection output signal OUTN of the comparator 10A changes when a current I2 flowing through a transistor MP3 and a current I3 flowing through a transistor MP4 have the same current value, a current value of a current I1 and a resistance value of Ros are set such that I1 × (1/2) × Ros = 0.1 V is satisfied.

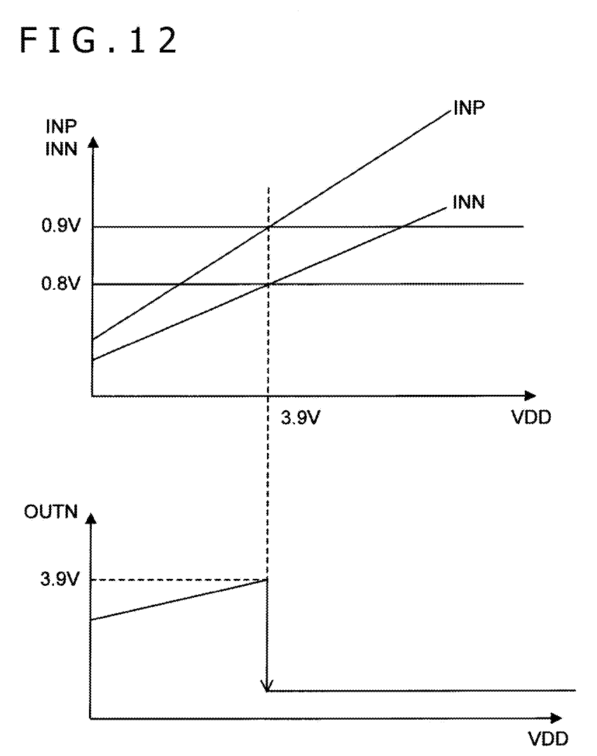

FIG. 12 is a diagram for depicting an example of a relation between a change in the power supply voltage VDD and a change in the signal level of the detection output signal OUTN of the comparator 10A in the modified example of the first embodiment.

In a case where the power supply voltage VDD is equal to or smaller than 3.9 V, since INP ≤ INN + I2 × Ros is satisfied, the detection output signal OUTN of the comparator 10A is at the H level. On the other hand, when the power supply voltage VDD becomes larger than 3.93 V, since INP > INN + I2 × Ros is satisfied, the detection output signal OUTN of the comparator 10A is at the L level. Accordingly, on the basis of the signal level of the detection output signal OUTN, it is possible to detect that the power supply voltage VDD has risen above the determination threshold voltage VTH = 3.9 V, that is, that the power supply voltage VDD is an overvoltage.

In addition, in each of the embodiments described above, the case where the resistor string RA or RB includes a plurality of resistors connected in series between the voltage supply line of the power supply voltage VDD and the supply line of the ground potential GND has been described as an example. However, the configuration of the resistor string is not limited to this, and it is sufficient if the resistor string is configured as a voltage dividing section that divides the power supply voltage VDD at different resistance ratios and outputs the divided voltages. In addition, a predetermined potential other than the ground potential GND may be used.

### Supplementary Note

The following configurations are disclosed in this specification.

### Configuration 1

A voltage change detection circuit for detecting that a power supply voltage crosses a threshold value, the circuit including:
a voltage dividing section that outputs each of a first voltage obtained by dividing a voltage between the power supply voltage and a predetermined potential at a first voltage dividing ratio and a second voltage obtained by dividing a voltage between the power supply voltage and a predetermined potential at a second voltage dividing ratio; and
a comparator that compares the first voltage with a voltage obtained by adding an offset voltage based on the threshold value to the second voltage,
in which a result of comparison by the comparator is output as a detection output signal indicating whether or not the power supply voltage crosses the threshold value.

### Configuration 2

The voltage change detection circuit according to Configuration 1,
in which the voltage dividing section includes a resistor string in which a plurality of resistors are connected in series, the power supply voltage is applied to one end of the resistor string, the other end thereof is connected to a predetermined potential, and potentials of connection nodes connecting the plurality of resistors to each other are output as the first voltage and the second voltage.

### Configuration 3

The voltage change detection circuit according to Configuration 1 or 2,
in which the comparator includes
a first transistor to which the first voltage is applied,
a second transistor which constitutes a differential pair with the first transistor and to which the second voltage is applied, and
a variable resistor which is connected in series to the second transistor and has a variable resistance value, and
the first voltage is compared with a voltage obtained by adding a voltage across the variable resistor as the offset voltage to the second voltage.

### Configuration 4

The voltage change detection circuit according to Configuration 1 or 2,
in which the comparator includes
a first transistor to which the first voltage is applied, and
a second transistor which constitutes a differential pair with the first transistor, to which the second voltage is applied, and whose gate length is adjustable.

### Configuration 5

The voltage change detection circuit according to any one of Configurations 1 to 4,
in which the comparator includes
a comparison section that compares the first voltage with a voltage obtained by adding the offset voltage based on the threshold value to the second voltage,
a logic gate circuit that receives an input of a result of comparison by the comparison section at a first input terminal, receives an input of a reset signal at a second input terminal, and outputs a logic operation signal indicating a result of performing a logic operation on the basis of the result of comparison and the reset signal, and
an RS latch circuit that receives inputs of the logic operation signal and a signal obtained by inverting the logic operation signal and outputs each of the detection output signal and a signal obtained by inverting the detection output signal.

### Configuration 6

The voltage change detection circuit according to Configuration 5,
in which the logic gate circuit is a NOR circuit.

### Configuration 7

The voltage change detection circuit according to Configuration 6,
in which the logic gate circuit is a NAND circuit.
It should be understood by those skilled in the art that various modifications, combinations, sub-combinations and alterations may occur depending on design requirements and other factors insofar as they are within the scope of the appended claims or the equivalent thereof.

The present disclosure contains subject matter related to that disclosed in Japanese Priority Patent Application JP 2025-073142 filed in the Japan Patent Office on Apr. 25, 2025, the entire content of which is hereby incorporated by reference.

What is claimed is:

1. A voltage change detection circuit for detecting that a power supply voltage crosses a threshold value, the circuit comprising:
a voltage dividing section that outputs each of a first voltage obtained by dividing a voltage between the power supply voltage and a predetermined potential at a first voltage dividing ratio and a second voltage obtained by dividing a voltage between the power supply voltage and a predetermined potential at a second voltage dividing ratio; and
a comparator that compares the first voltage with a voltage obtained by adding an offset voltage based on the threshold value to the second voltage,
wherein a result of comparison by the comparator is output as a detection output signal indicating whether or not the power supply voltage crosses the threshold value.

2. The voltage change detection circuit according to claim 1,
wherein the voltage dividing section includes a resistor string in which a plurality of resistors are connected in series, the power supply voltage is applied to one end of the resistor string, the other end thereof is connected to a predetermined potential, and potentials of connection nodes connecting the plurality of resistors to each other are output as the first voltage and the second voltage.

3. The voltage change detection circuit according to claim 1,
wherein the comparator includes
a first transistor to which the first voltage is applied,
a second transistor which constitutes a differential pair with the first transistor and to which the second voltage is applied, and
a variable resistor which is connected in series to the second transistor and has a variable resistance value, and
the first voltage is compared with a voltage obtained by adding a voltage across the variable resistor as the offset voltage to the second voltage.

4. The voltage change detection circuit according to claim 1,
wherein the comparator includes
a first transistor to which the first voltage is applied, and
a second transistor which constitutes a differential pair with the first transistor, to which the second voltage is applied, and whose gate length is adjustable.

5. The voltage change detection circuit according to claim 1,
wherein the comparator includes
a comparison section that compares the first voltage with a voltage obtained by adding the offset voltage based on the threshold value to the second voltage,
a logic gate circuit that receives an input of a result of comparison by the comparison section at a first input terminal, receives an input of a reset signal at a second input terminal, and outputs a logic operation signal indicating a result of performing a logic operation on a basis of the result of comparison and the reset signal, and
an RS latch circuit that receives inputs of the logic operation signal and a signal obtained by inverting the logic operation signal and outputs each of the detection output signal and a signal obtained by inverting the detection output signal.

6. The voltage change detection circuit according to claim 5,
wherein the logic gate circuit is a NOR circuit.

7. The voltage change detection circuit according to claim 6,
wherein the logic gate circuit is a NAND circuit.
